(19) United States
(12) Patent Application Publication
(10) Pub. No.: US 2018/0240605 A1
(43) Pub. Date: Aug. 23, 2018

(54) ELECTRONIC COMPONENT

(71) Applicant: FUJITSU LIMITED, Kawasaki-shi (JP)

(72) Inventors: Tomokazu NAKASHIMA, Kawasaki (JP); Masayuki ITOH, Kawasaki (JP); Yoshinori MESAKI, Yokohama (JP)

(73) Assignee: FUJITSU LIMITED, Kawasaki-shi (JP)

(21) Appl. No.: 15/892,452

(22) Filed: Feb. 9, 2018

(30) Foreign Application Priority Data
Feb. 20, 2017 (JP) 2017-028815

(51) Int. Cl. H01G 9/10; H01G 9/008; H05K 1/18; H05K 3/34

(52) U.S. Cl. CPC H01G 9/10; H01G 9/008; H05K 2201/10015; H05K 3/3426; H05K 1/181

(57) ABSTRACT

An electronic component includes a main body mounted over a board, a case that houses the main body, a base member that is arranged between the case and the board, a lead that extends out from the main body and penetrates through the base member to be joined onto the board, and a leg that extends out from the case and penetrates through the base member to be joined to the board.

### CROSS-REFERENCE TO RELATED APPLICATION

This application is based upon and claims the benefit of priority of the prior Japanese Patent Application No. 2017-28815, filed on Feb. 20, 2017, the entire contents of which are incorporated herein by reference.

### FIELD

The embodiment discussed herein is related to an electronic component.

### BACKGROUND

There is a surface mount electronic component (a surface mount component) such as an aluminum electrolytic capacitor. This type of electronic component has, for example, an electronic component main body, a case that houses the electronic component main body, a seal member that seals an opening of the case, an insulation plate facing the seal member, and a pair of leads extending out from the component main body. The pair of leads penetrates through the seal member and the insulation plate, and are soldered to a board.

Here, the seal member is provided with a pair of lock members. The pair of lock members penetrate through the insulation plate, and are soldered to the board. The case is fixed onto the board with the pair of lock members, and thus vibration of the case and the leads are reduced.

However, the pair of lock members are provided on the seal member; that is, the case is fixed onto the board via the pair of lock members and the seal member. Thus, there is a possibility that the vibrations of the case and the pair of leads are not reduced enough, stress is accordingly concentrated at a joint between the pair of leads and the board, and finally the pair of leads break.

The followings are reference documents.
[Document 1] Japanese Laid-open Patent Publication No. 2002-110460 and
[Document 2] Japanese Laid-open Patent Publication No. 2000-156330.

### SUMMARY

According to an aspect of the invention, an electronic component includes a main body mounted over a board, a case that houses the main body, a base member that is arranged between the case and the board, a lead that extends out from the main body and penetrates through the base member to be joined onto the board, and a leg that extends out from the case and penetrates through the base member to be joined to the board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view taken along line I-I in FIG. 6 that illustrates a state where an electronic component according to an embodiment is mounted on a board;

FIG. 2 is a cross-sectional view taken along line II-II in FIG. 6 that illustrates the state where the electronic component according to the embodiment is mounted on the board;

FIG. 3 is an exploded side view that illustrates a case and a base member of the electronic component according to the embodiment;

FIG. 4 is an exploded cross-sectional view corresponding to FIG. 2 that illustrates the case and the base member of the electronic component according to the embodiment;

FIG. 5 is an exploded cross-sectional view corresponding to FIG. 2 that illustrates the electronic component according to the embodiment and the board;

FIG. 6 is a plan view of the electronic component illustrated in FIG. 5 as seen from the base member side;

FIG. 7 is a cross-sectional view corresponding to FIG. 2 that illustrates a process of assembling the case and the base member of the electronic component according to the embodiment;

FIG. 8 is a perspective view that illustrates a terminal of a lead illustrated in FIG. 1;

FIG. 9 is a plan view of the board illustrated in FIG. 1 as seen from the side of the surface of that board; and

FIG. 10 is a plan view of the base member as seen from the side of a facing surface of that base member.

### DESCRIPTION OF EMBODIMENT

An embodiment of the technology disclosed in the present application is hereinafter described.

[Electronic Component]

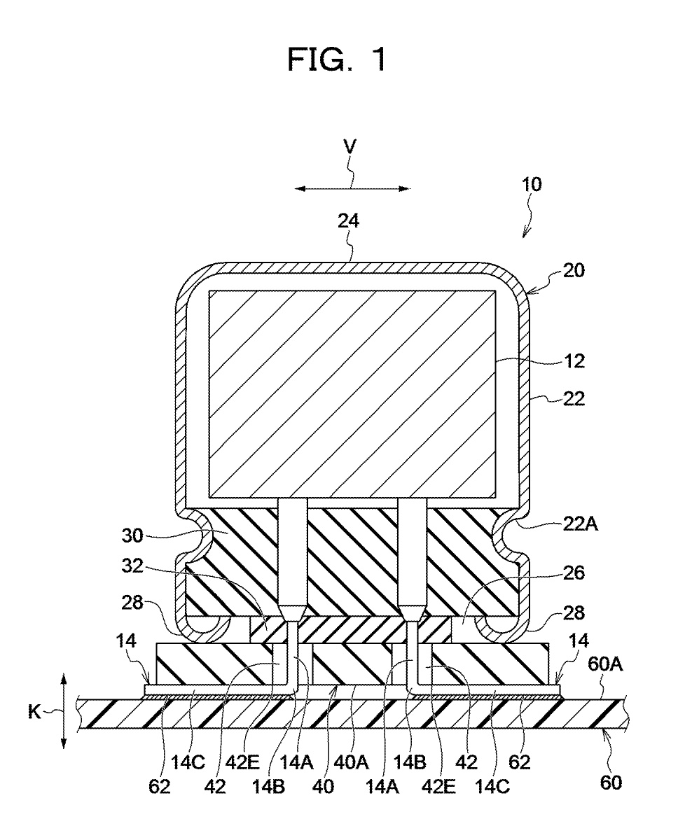

As illustrated in FIG. 1, an electronic component 10 may be a surface mount component such as an aluminum electrolytic capacitor and the like, for example. This electronic component 10 has an electronic component main body 12, a case 20, a seal member 30, and a base member 40.

[Electronic Component Main Body]

The electronic component main body 12 may be an element (an internal element) for a capacitor having anode aluminum foil, electrolytic paper, cathode aluminum foil, and electrolyte, for example. In addition, the electronic component main body 12 has a pair of leads (lead wires) 14. This electronic component main body 12 is housed in the case 20. The pair of leads 14 are described later.

[Case]

The case 20 is formed of a metal such as aluminum. This metallic case 20 is shaped as a pipe including closed one end. In specific, the case 20 has a pipe portion 22 and a bottom wall 24. The pipe portion 22 is shaped as a pipe (a cylinder). The bottom wall 24 is provided on the one end side in the axial direction of this pipe portion 22. The bottom wall 24 closes an opening at the one end side of the pipe portion 22. The pipe portion 22 has a constriction 22A, which is described later.

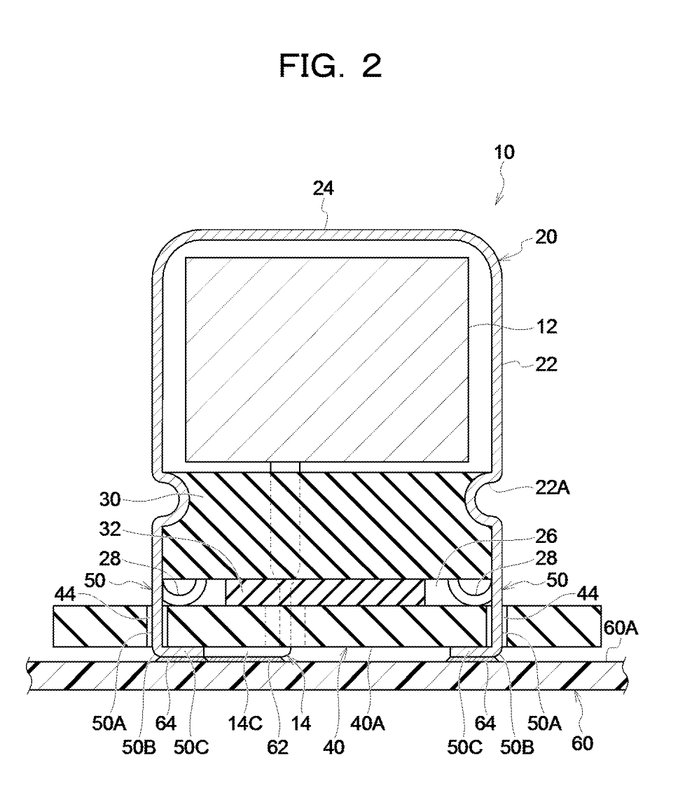

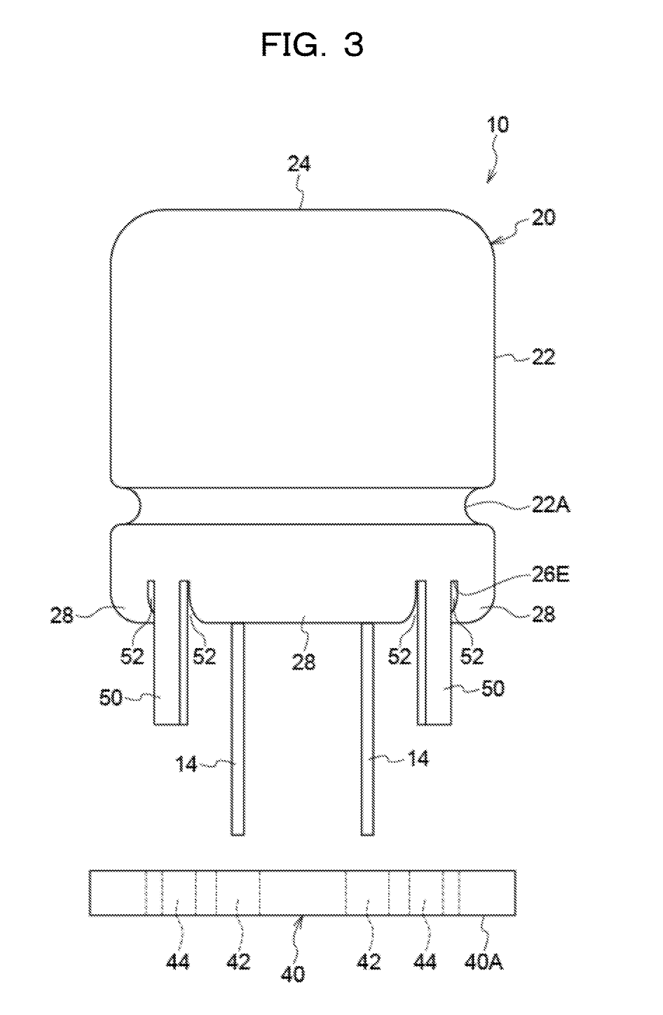

As illustrated in FIG. 2, the case 20 has an opening 26, multiple folded portions 28 and multiple legs 50. The opening 26 is formed on the other end side in the axial direction of the pipe portion 22. The electronic component main body 12 is housed into the case 20 from this opening 26. In addition, as illustrated in FIG. 3, the multiple folded portions 28 are provided on a periphery 26E of the opening 26.

As illustrated in FIG. 1, each of the folded portions 28 is formed by folding the other end of the pipe portion 22 to the inside of the opening 26. The cross-section of the folded portion 28 may be in a U-shape. These folded portions 28 support the seal member 30, which is described later. In addition, each of the later-described legs 50 (see FIG. 3) is provided between the adjacent folded portions 28.

[Seal Member]

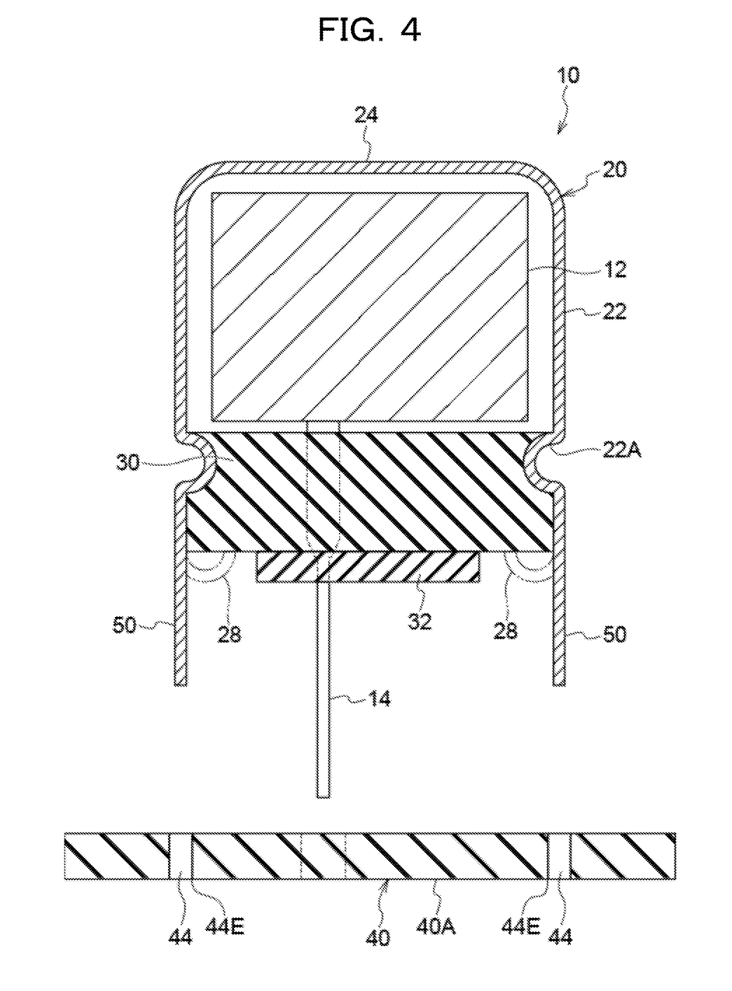

The seal member 30 is formed of an elastic body such as rubber, for example. In addition, as illustrated in FIG. 4, the seal member 30 is fitted into the opening 26 of the case 20 while the electronic component main body 12 is already housed in the case 20. The pair of leads 14 extending out from the electronic component main body 12 (see FIG. 1) penetrate through this seal member 30.

A portion of the pipe portion 22 in which the seal member 30 is fitted is swaged by processing such as raising. This forms the constriction 22A that makes a dent on the pipe portion 22, and while the seal member 30 is fixed in the pipe portion 22, the seal member 30 seals the opening 26 of the case 20.

After the seal member 30 seals the opening 26 of the case 20, the folded portions 28 are formed on the case 20 as depicted by a long dashed double-short dashed line. These folded portions 28 support the seal member 30, and thus the seal member 30 is inhibited from being dropped out.

[Base Member]

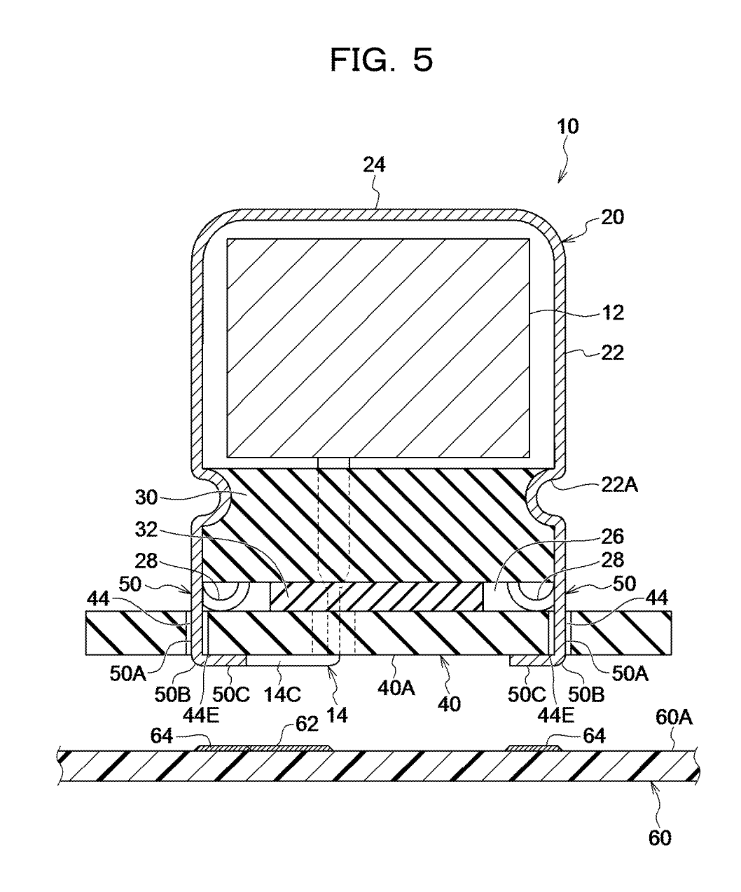

As illustrated in FIG. 5, the base member 40 may be an insulation plate that insulates terminals 14C of the pair of leads 14, which are described later, from the case 20. This base member 40 is made of resin and the like and has a rectangular shape or a polygonal shape for indicating polarities. The base member 40 is arranged between the folded portions 28 of the case 20 and a surface 60A of a board 60, and faces the seal member 30. A surface of this base member 40 on the board 60 side (the opposite side from the case 20) may be a facing surface 40A that faces the surface 60A of the board 60.

A height adjuster 32 protruding toward the base member 40 is provided on the seal member 30. The height adjuster 32 is integrally formed with the seal member 30. As appropriate, it is possible to omit the seal member 30 and the height adjuster 32.

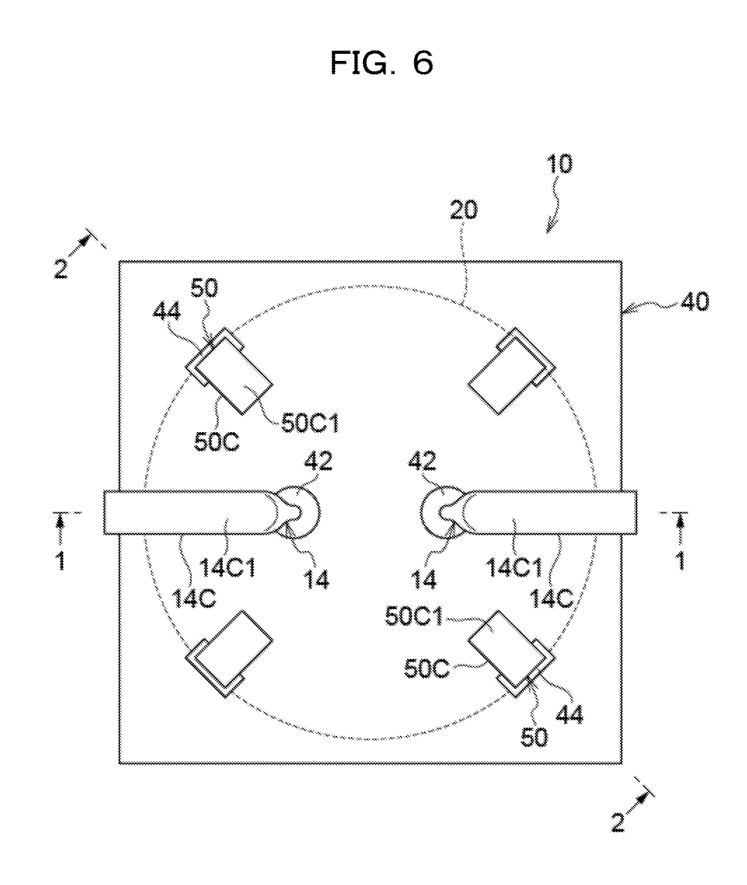

As illustrated in FIG. 6, the base member 40 has a pair of lead through-holes 42 and multiple leg through-holes 44. The pair of lead through-holes 42 are formed in the center of the base member 40. Each of the pair of lead through-holes 42 may be a circular through-hole penetrating through the base member 40 in the thickness direction. The pair of lead through-holes 42 are arranged at a distance from each other. Each of the pair of leads 14 passes through corresponding one of the pair of lead through-holes 42.

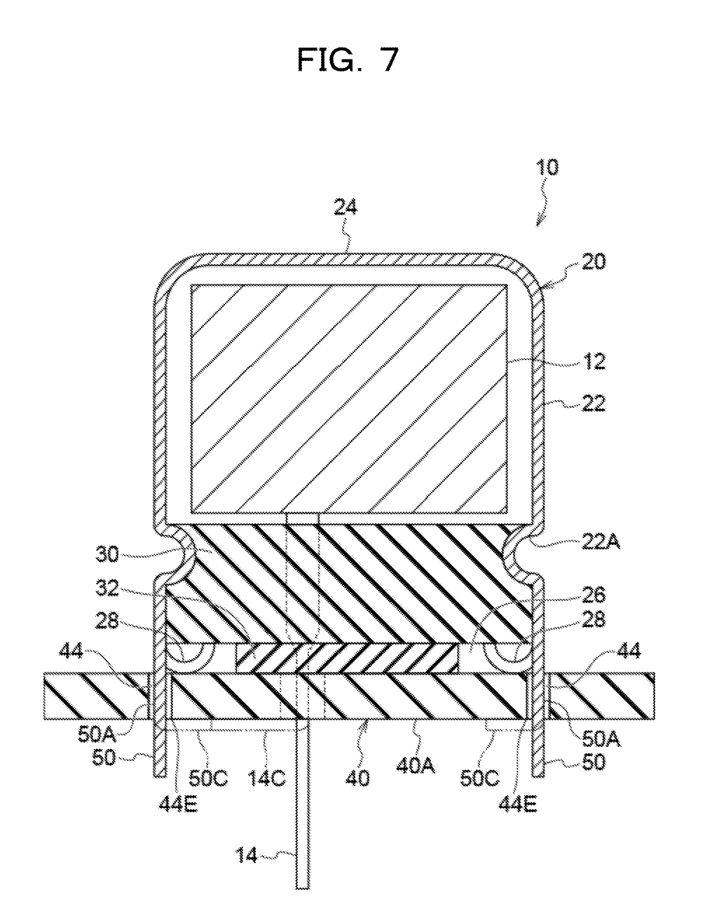

As depicted by a long dashed double-short dashed line in FIG. 7, while the lead 14 passes through the lead through-hole 42, the distal end of the lead 14 is bent toward the outer periphery side of the base member 40. In specific, as illustrated in FIG. 1, the lead 14 has a bend portion 14B. The bend portion 14B is bent in an L-shape along an edge 42E of the lead through-hole 42 on the board 60 side. This forms the terminal 14C joined to the board 60 on a further distal side of the lead 14 from the bend portion 14B. The terminal 14C is arranged along the facing surface 40A of the base member 40.

Meanwhile, a portion on a further proximal side (the electronic component main body 12 side) of the lead 14 from the bend portion 14B may be a wiring portion 14A that connects the electronic component main body 12 and the terminal 14C. The wiring portion 14A extends out from the electronic component main body 12 and passes through the lead through-hole 42.

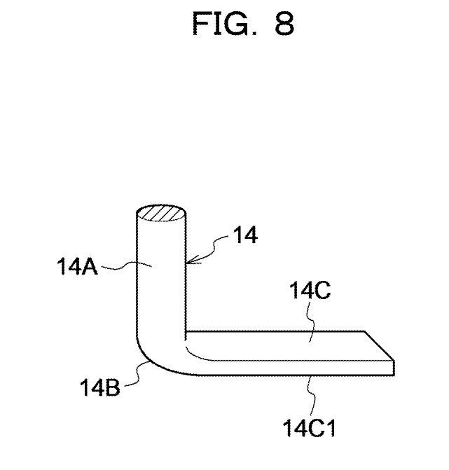

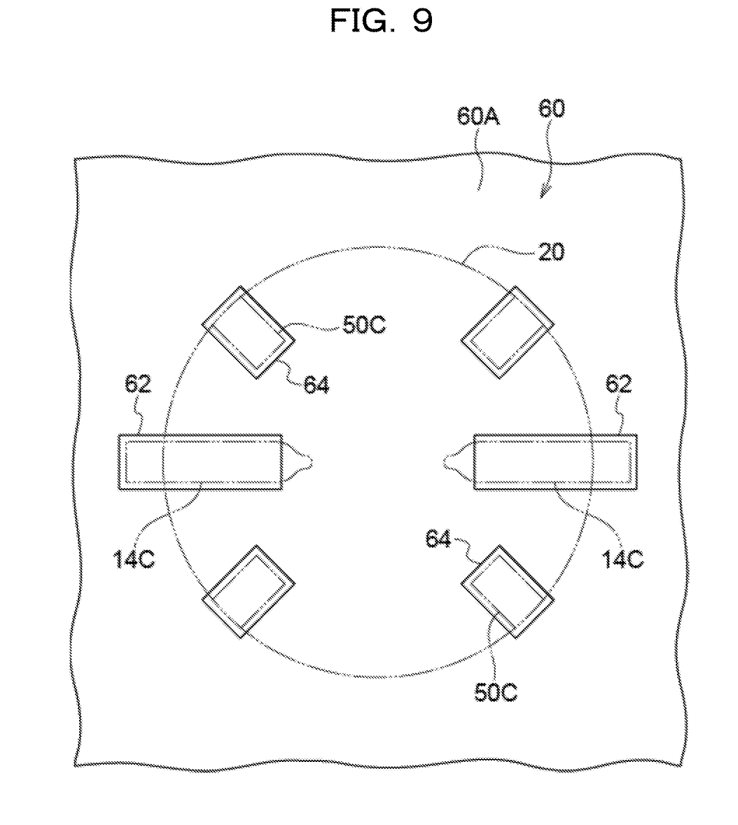

As illustrated in FIG. 8, the terminal 14C is crushed into a flat plate shape. A surface of this terminal 14C on the board 60 side (the opposite side from the base member 40) may be a joint surface 14C1. Meanwhile, as illustrated in FIG. 9, a pair of lead patterns 62 are formed on the surface 60A of the board 60. The pair of lead patterns 62 may be conductor patterns using copper foil and the like, for example. The joint surface 14C1 of the terminal 14C of each of the pair of leads 14 is electrically joined to corresponding one of the pair of lead patterns 62 by soldering. The electronic component main body 12 and the board 60 are thus electrically connected.

The multiple leg through-holes 44 are formed in the outer periphery of the base member 40. Each of the multiple leg through-holes 44 may be a rectangular through-hole penetrating through the base member 40 in the thickness direction. These multiple leg through-holes 44 are arranged at a distance from each other in the outer periphery of the base member 40 so as to surround the lead through-holes 42. Each of the legs 50 of the case 20 passes through the corresponding leg through-hole 44.

[Leg]

As illustrated in FIG. 3, the multiple legs 50 and the multiple folded portions 28 are alternately provided on the periphery 26E of the opening 26 of the case 20. The case 20 and the legs 50 may be formed of a metal plate, and the pipe portion 22 and the legs 50 may be formed integrally. In other words, the legs 50 may be a portion of the case 20. Each leg 50 may be a portion extending out to the base member 40 side from the end of the case 20 (the pipe portion 22) on the base member 40 side without being folded to the opening 26 side. A notch 52 is formed between the leg 50 and the corresponding folded portion 28.

As depicted by a long dashed double-short dashed line in FIG. 7, while the leg 50 passes through the leg through-hole 44, the distal end of the leg 50 is bent toward the center side of the base member 40. In specific, as illustrated in FIG. 5, the leg 50 has a bend portion 50B. The bend portion 50B is bent in an L-shape toward the center side of the base member 40 along an edge 44E of the leg through-hole 44 on the board 60 side. This forms a joint 50C joined to the board 60 on a further distal side of the leg 50 from the bend portion 50B. The joint 50C is arranged along the facing surface 40A of the base member 40.

Meanwhile, a portion on a further proximal side (the opening 26 side) of the leg 50 from the bend portion 50B may be a stopper 50A. The stopper 50A extends out from the periphery 26E of the opening 26 (see FIG. 3) and passes through the leg through-hole 44.

As illustrated in FIG. 6, the leg 50 is bent so as not to allow the joint 50C to contact the terminal 14C of each of the pair of leads 14. The joint 50C and the terminal 14C of each of the pair of leads 14 are thus arranged at a distance from each other. This inhibits short-circuit of the pair of leads 14.

A surface of the joint 50C on the board 60 side (the opposite side of the base member 40) may be a joint surface 50C1. Meanwhile, as illustrated in FIG. 9, multiple leg patterns 64 are formed on the surface 60A of the board 60. The leg patterns 64 may be conductor patterns using copper foil and the like, for example. The joint surface 50C1 of each of the multiple joints 50C is joined to corresponding one of these leg patterns 64 by soldering. The case 20 is thus fixed onto the board 60. Note that surface processing for soldering is applied to the joint surface 50C1 of the joint 50C.

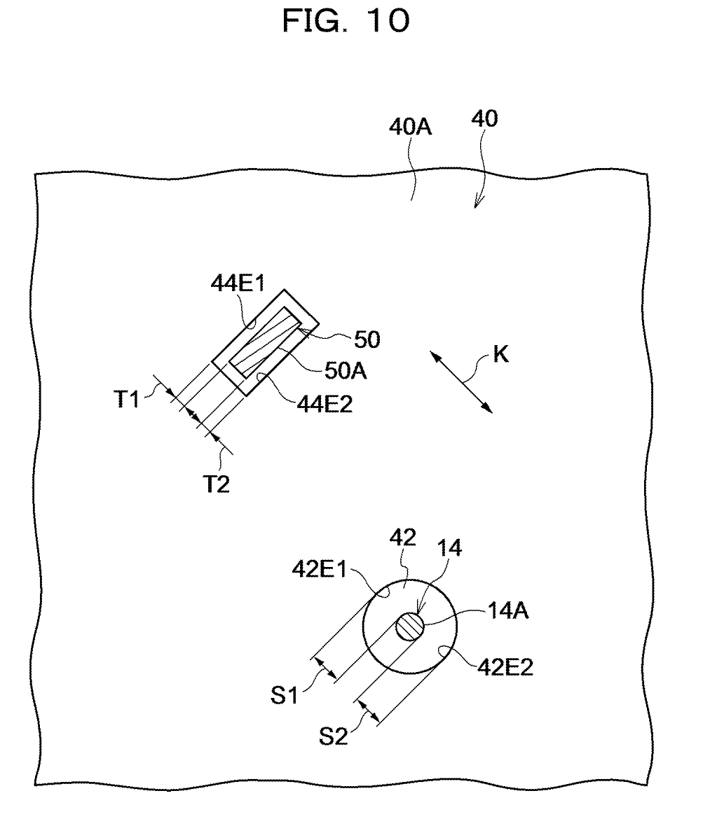

As illustrated in FIG. 10, an edge 44E1 of the leg through-hole 44 is arranged on one side in a predetermined direction (a direction of arrow K) of the stopper 50A of the leg 50. A clearance T1 is formed between this edge 44E1 and the stopper 50A. Meanwhile, an edge 44E2 of the leg through-hole 44 is arranged on the other side in the predetermined direction of the stopper 50A of the leg 50. A clearance T2 is formed between this edge 44E2 and the stopper 50A.

Likewise, an edge 42E1 of the lead through-hole 42 is arranged on one side in the predetermined direction (the direction of arrow K) of the wiring portion 14A of the lead 14. A clearance S1 is formed between this edge 42E1 and the wiring portion 14A. Meanwhile, an edge 42E2 of the lead through-hole 42 is arranged on the other side in the predetermined direction of the wiring portion 14A of the lead 14. A clearance S2 is formed between this edge 42E2 and the wiring portion 14A.

In this case, the clearance S1 on the one side in the predetermined direction of the wiring portion 14A may be equal to or larger than the clearance T1 on the one side in the predetermined direction of the stopper 50A (S1≥T1). Likewise, the clearance S2 on the other side in the predetermined direction of the wiring portion 14A may be equal to or larger than the clearance T2 on the other side in the predetermined direction of the stopper 50A (S2≥T2). Thus, when the base member 40 vibrates in a predetermined direction, the stopper 50A contacts the edges 44E1 and 44E2 of the leg through-hole 44 before the wiring portion 14A contacts the edges 42E1 and 42E2 of the lead through-hole 42.

Note that, in this embodiment, a size of a portion such as the leg through-hole 44 is set such that the stopper 50A contacts the edges of the leg through-hole 44 before the wiring portion 14A contacts the edges of the lead through-hole 42 even when the base member 40 vibrates in a direction crossing the predetermined direction.

[Operations]

Next, operations of this embodiment are described.

FIG. 1 illustrates the electronic component 10 mounted on the surface 60A of the board 60. When the case 20 vibrates in an orthogonal direction (a direction of arrow V) orthogonal to a thickness direction (the direction of arrow K) of the board 60 in this state, each lead 14 is deformed at the bend portion 14B (a joint between the lead 14 and the board 60). Thus, there is a possibility that stress is concentrated at the bend portion 14B and finally that bend portion 14B breaks.

In addition, when the base member 40 vibrates in the orthogonal (the direction of arrow V) direction, there is a possibility that the edge 42E of the lead through-hole 42 contacts the bend portion 14B of the lead 14 and finally that bend portion 14B breaks.

On the other hand, in this embodiment, the case 20 of the electronic component 10 has the multiple legs 50, as illustrated in FIG. 2. The multiple legs 50 pass through the leg through-holes 44 in the base member 40 while extending out from the case 20, and are joined to the leg patterns 64 on the board 60 by soldering, respectively. The case 20 is directly joined onto the board 60 by these legs 50.

With this, vibrations of the case 20 and the pair of leads 14 extending out from the electronic component main body 12 housed in the case 20 are reduced. This lessens the stress applied to the bend portions 14B of the pair of leads 14. Thus, the bend portions 14B of the pair of leads 14 are inhibited from being broken.

In addition, the legs 50 may be formed integrally with the case 20. In other words, the legs 50 may be a portion of the case 20. In this embodiment, the number of parts of the electronic component 10 is accordingly less than that in the case where the legs 50 and the case 20 are formed as different pieces. Thus, for example, the number of steps for assembling the electronic component 10 is decreased.

Moreover, the surface processing for soldering is applied to the joint surface 50C1 of the joint 50C of each leg 50. This makes soldering-joint between the joint 50 and the corresponding leg pattern 64 easy.

Further, the joint 50C of the leg 50 is arranged along the facing surface 40A of the base member 40. The base member 40 is held between this joint 50C and the folded portion 28 of the case 20. This also reduces vibration of the base member 40. As a result, contact between each bend portion 14B of the lead 14 and the edge 42E of the corresponding lead through-hole 42 is inhibited. Thus, the bend portion 14B of the lead 14 is inhibited from being broken.

In this case, for example, a desirable vibration strength desirable for an electronic component used in a vehicle and the like having severe vibrations is an acceleration of at least 500 m/s². Regarding this, a vibration strength of the electronic component 10 according to this embodiment is an acceleration of about 700 m/s², and thus it is possible to meet the above desirable vibration strength. On the other hand, a vibration strength of an electronic component having no legs such as the legs 50 in this embodiment is an acceleration of about 100 m/s², which does not meet the above desirable vibration strength.

In addition, as illustrated in FIG. 10, the clearance S1 on the one side in the predetermined direction of the wiring portion 14A may be equal to or larger than the clearance T1 on the one side in the predetermined direction of the stopper 50A (S1≥T1). Likewise, the clearance S2 on the other side in the predetermined direction of the wiring portion 14A may be equal to or larger than the clearance T2 on the other side in the predetermined direction of the stopper 50A (S2≥T2).

With this, when the base member 40 vibrates in the predetermined direction (the direction of arrow K), the stopper 50A contacts the edges 44E1 and 44E2 of the leg through-hole 44 before the wiring portion 14A contacts the edges 42E1 and 42E2 of the lead through-hole 42. Thus, the bend portion 14B of the lead 14 is inhibited from being broken.

Likewise, also when the base member 40 vibrates in the direction orthogonal to the predetermined direction, the stopper 50A contacts the edges of the leg through-hole 44 before the wiring portion 14A contacts the edges of the lead through-hole 42. Thus, the bend portion 14B of the lead 14 is inhibited from being broken.

If the stopper 50A is allowed to contact the edges of the leg through-hole 44 before the wiring portion 14A contacts the edges of the lead through-hole 42 like this, it is possible to increase the vibration strength of the above-described electronic component 10 as an acceleration of about 1000 m/s².

In addition, in this embodiment, the base member 40 insulates the terminals 14C of the pair of leads 14 from the case 20. Further, each of the terminals 14C of the leads 14 and each of the joints 50C of the legs 50 are arranged at a distance from each other. This inhibits short-circuit of the terminals 14C of the pair of leads 14.

[Modification]

Next, a modification of the above embodiment is described.

In the above embodiment, the joints 50C of the legs 50 are bent toward the center side of the base member 40; however, the joints 50C of the legs 50 may be bent toward the outer periphery side of the base member 40.

In addition, in the above embodiment, the leads 14 and the legs 50 are soldered to the board 60 while the distal sides thereof are bent; however, the leads and the legs may be joined onto the board 60 without being bent.

Moreover, as appropriate, shapes and arrangements of the legs 50 may be changed. Further, the case 20 may be provided with at least one leg 50.

Furthermore, in the above embodiment, the leads 14 and the legs 50 are soldered to the board 60; however, the leads 14 may be electrically joined onto the board 60 by brazing, bonding, or the like. In addition, the legs 50 may be joined onto the board 60 by brazing, bonding, or the like. Note that it is unnecessary to electrically join the legs 50 and the board 60.

In the above embodiment, the clearance S1 on the one side in the predetermined direction of the wiring portion 14A may be equal to or larger than the clearance T1 on the one side in the predetermined direction of the stopper 50A (S1 T1); however, the clearance S1 of the wiring portion 14A may be smaller than the clearance T1 of the stopper 50A (S1<T1). Likewise, although the clearance S2 on the other side in the predetermined direction of the wiring portion 14A may be equal to or larger than the clearance T2 on the other side in the predetermined direction of the stopper 50A (S2≥T2), the clearance S2 of the wiring portion 14A may be smaller than the clearance T2 of the stopper 50A (S2<T2).

In the above embodiment, when the base member 40 vibrates in the direction orthogonal to the predetermined direction, the stopper 50A contacts the edges of the leg through-hole 44 before the wiring portion 14A contacts the edges of the lead through-hole 42; however, when the base member 40 vibrates in the direction orthogonal to the predetermined direction, the wiring portion 14A may contact the edges of the lead through-hole 42 before the stopper 50A contacts the edges of the leg through-hole 44.

In the above embodiment, the case 20 may be made of a metal; however, the case may be made of resin or the like. For example, when the leads 14 have insulating coating, the base member may not be limited to be an insulation plate and may be another member.

As appropriate, the above embodiment is not limited to be applied to an aluminum electrolytic capacitor, and it is possible to apply the above embodiment to another electronic component.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic component comprising:
a main body mounted over a board;
a case that houses the main body;
a base member that is arranged between the case and the board;
a lead that extends out from the main body and penetrates through the base member to be joined onto the board; and
a leg that extends out from the case and penetrates through the base member to be joined to the board.

2. The electronic component according to claim 1, wherein
the base member has a facing surface that faces the board,
a distal side of the lead is a terminal that is joined onto the board while being bent toward a side of the facing surface, and
a distal side of the leg is a joint that is joined onto the board while being bent toward a side of the facing surface.

3. The electronic component according to claim 2, wherein
the joint is arranged along the facing surface of the base member, and
the base member is held between the joint and the case.

4. The electronic component according to claim 2, wherein
the joint is bent toward a center side of the base member.

5. The electronic component according to claim 2, wherein
the terminal and the joint are arranged at a distance from each other.

6. The electronic component according to claim 2, wherein
the joint is joined onto a surface of the board.

7. The electronic component according to claim 6, wherein
the joint has a joint surface that is soldered onto the surface of the board, and
surface processing for soldering is applied to the joint surface.

8. The electronic component according to claim 2, wherein
the terminal is joined onto a surface of the board.

9. The electronic component according to claim 8, wherein
the terminal is soldered onto the surface of the board.

10. The electronic component according to claim 1, wherein
the case has an opening on a side of the base member of the case, and
the leg extends out from a periphery of the opening.

11. The electronic component according to claim 10, further comprising a seal member that seals the opening, wherein
the lead penetrates through the seal member and the base member.

12. The electronic component according to claim 11, wherein
the case has a folded portion that extends out from the periphery of the opening to an inside of the opening and supports the seal member.

13. The electronic component according to claim 12, wherein
the base member is held between the folded portion and the joint.

14. The electronic component according to claim 1, wherein
the base member has
a lead through-hole through which the lead passes and
a leg through-hole through which the leg passes, and
a clearance between the lead and an edge of the lead through-hole on one side of the lead is equal to or larger than a clearance between the leg and an edge of the leg through-hole on one side of the leg.

15. The electronic component according to claim 1, wherein
a plurality of legs, each of which is the leg, extend from the case.

16. The electronic component according to claim 1, wherein
the case and the leg are formed integrally.

17. The electronic component according to claim 1, wherein
the base member is an insulation plate.

18. The electronic component according to claim 1, wherein
the case is made of a metal.

19. The electronic component according to claim 1, wherein
the main body is an aluminum electrolytic capacitor.

20. A circuit board comprising:
a board; and
an electronic component that mounted over the board and has a main body, a case that houses the main body, a base member that is arranged between the case and the board, a lead that extends out from the main body and penetrates through the base member to be joined onto the board, and a leg that extends out from the case and penetrates through the base member to be joined to the board.
